(19) United States
(12) Patent Application Publication
(10) Pub. No.: US 2016/0141476 A1
(43) Pub. Date: May 19, 2016

(54) PACKAGE STRUCTURE AND METHOD OF MANUFACTURE THEREOF, AND CARRIER

(71) Applicant: ACHROLUX INC., Sunnyvale, CA (US)

(72) Inventors: Peiching Ling, Sunnyvale, CA (US); Dutta Vivek, Sunnyvale, CA (US); Dezhong Liu, Sunnyvale, CA (US)

(21) Appl. No.: 14/944,393

(22) Filed: Nov. 18, 2015

(30) Foreign Application Priority Data
Nov. 18, 2014 (TW) 103139873

(51) Int. Cl. H01L 33/62; H01L 33/50; H01L 33/48; H01L 33/54

(52) U.S. Cl. CPC H01L 33/62; H01L 33/54; H01L 33/505; H01L 33/483; H01L 2933/005; H01L 2933/0041; H01L 2933/0066; H01L 2933/0033

(57) ABSTRACT

The present disclosure provides a method of manufacturing a package structure. The method includes: providing a plurality of conductive portions and a light emitting element; encapsulating the light emitting element and the conductive portions by an encapsulant with a lateral surface of the light emitting element electrically insulated from the conductive portions; electrically connecting the light emitting element to the conductive portions by a conductive element. Accordingly, several methods can be selected to form the conductive element with no conventional limitations. The present disclosure further provides a package structure and a carrier.

### BACKGROUND OF THE INVENTION

1. Field of the Invention

The present disclosure relates to a packaging structure and a manufacturing method thereof, and, more particularly, to a light emitting package structure and a manufacturing method thereof.

2. Description of Related Art

With the booming development in the electronic industry, electronic products gradually become compact in form, and the research is focused on the functionality pursuits for high performance, high functionality, and high processing speed. Light-emitting diodes (LEDs) are variously employed in electronic products that require lighting due to the advantages of long lifecycle, small volume, high shock resistance, and low power consumption. Therefore, the application of LEDs becomes popular in industry, various electronic products, and appliances.

FIGS. 1A-1B illustrate sectional scheme views of a method for manufacturing an LED package 1 according to conventional art. The method includes: forming a reflection cup 11 having an opening 110 on a substrate 10; disposing an LED element 12 in the opening 110, followed by utilizing a plurality of wires 120 such as golden wires to electrically connect the LED element 12 to the substrate 10; and encapsulating the LED element 12 with an encapsulant 13 having a phosphor powder layer.

However, in the method for manufacturing the LED package 1 according to the conventional art, the encapsulant 13 is formed after performing an electrical connection process. Accordingly, a lateral surface of the LED element 12 has no insulating material during the electrical connection process. As such, only the wire bonding process (e.g., forming the wires 120) can be selected. If a conductive adhesive is used, the conductive adhesive will tend to overflow to the lateral surface of the LED element 12. Consequently, a front surface (i.e., the P pole) and a lateral surface (i.e., the N pole) of the LED element 12 will be electrically connected and become short.

Therefore, the selection for a conductive element of the conventional LED package 1 is limited. Accordingly, how to overcome the issue of the limited selection for the conductive element in the prior art has become the problem desired to be solved.

### SUMMARY OF THE INVENTION

In view of the above-described drawbacks of the conventional art, the present disclosure provides a package structure, comprising: a light emitting element having an emitting side, a non-emitting side opposing to the emitting side, and a lateral surface adjacent the emitting side and the non-emitting side; an encapsulant directly covering the lateral surface of the light emitting element with the emitting side of the light emitting element exposed from the encapsulant; a plurality of conductive portions coupled into the encapsulant with a space between the lateral surface of the light emitting element and the conductive portions filled by the encapsulant; and at least one conductive element disposed on a surface of the encapsulant and electrically connecting the light emitting element with the conductive portions.

The present disclosure further provides a method of manufacturing a package structure, comprising: providing a plurality of conductive portions and at least one light emitting element, wherein the light emitting element has an emitting side, a non-emitting side opposing to the emitting side, and a lateral surface adjacent the emitting side and the non-emitting side; encapsulating the light emitting element and the conductive portions by an encapsulant, wherein the encapsulant covers the lateral surface of the light emitting element with a space between the lateral surface of the light emitting element and the conductive portions filled by the encapsulant and the emitting side of the light emitting element exposed from the encapsulant; and disposing at least one conductive element on a surface of the encapsulant to electrically connect the light emitting element with the conductive portions.

The present disclosure also provides a carrier, comprising: at least one placement portion; and a plurality of conductive portions, wherein on the same level basis with the placement portion, the conductive portions have a height higher than a height of the placement portion.

From the foregoing, the package structure and the method of manufacture thereof provide electrical isolation of the lateral surface of the light emitting element from other portions by covering the lateral surface of the light emitting element with an encapsulant. Accordingly, several methods for forming the conductive elements can be selected, thereby overcoming the issue with regard to limited selection for conductive elements in conventional art.

### BRIEF DESCRIPTION OF THE DRAWINGS

FIGS. 1A-1B illustrate sectional scheme views of a method for manufacturing an LED package according to the conventional art;

FIGS. 2A-2G″ illustrate sectional scheme views of a method for manufacturing a package structure according to the present disclosure, wherein FIG. 2B′ is a top view of

FIG. 2B; FIG. 2D′ is another embodiment of FIG. 2D; FIG. 2E′ is a different embodiment of FIG. 2E; and FIGS. 2G′ and 2G″ are different embodiments of FIG. 2G;

FIGS. 3A-3C illustrate sectional scheme views of another embodiment of a method for manufacturing a package structure according to the present disclosure;

FIGS. 4A-4C′ illustrate sectional scheme views of another embodiment of a method for manufacturing a package structure according to the present disclosure, wherein FIG. 4C′ is another embodiment of FIG. 4C;

FIGS. 5A-5B illustrate sectional and top scheme views of a package structure according to the present disclosure;

FIGS. 6A-6D illustrate sectional scheme views of another embodiment of a method for manufacturing a package structure according to the present disclosure;

FIGS. 7A-7D illustrate sectional scheme views of another embodiment of a method for manufacturing a package structure according to the present disclosure;

FIGS. 8A-8B illustrate sectional and top scheme views of another embodiment of a package structure according to the present disclosure; and

FIG. 9 illustrates a sectional scheme view of another embodiment of a package structure according to the present disclosure.

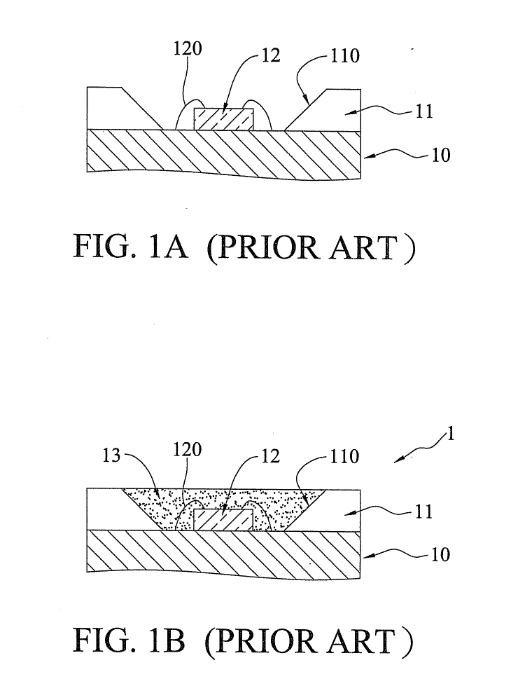

### DETAILED DESCRIPTION OF THE PREFERRED EMBODIMENTS

The following illustrative embodiments are provided to illustrate the disclosure of the present disclosure. These and other advantages and effects can be apparently understood by those in the art after reading the disclosure of this specification, and can be performed or applied by other different specific embodiments.

The structures, proportions, and sizes illustrated in the appended drawings of the specification of the present disclosure are merely for coping with the disclosure of the specification, in order to allow those skilled in the art to conceive and peruse it. The drawings are not for constraining the limitations of the present disclosure. Any structural modifications, alterations of proportions and adjustments of sizes, as long as not affecting the effect brought about by the present disclosure and the purpose achieved by the present disclosure, should fall within the range encompassed by the technical content disclosed in the present disclosure. Also, the referred terms such as “on,” “first,” “second” and “one” in this specification are only for the convenience to describe, not for limiting the scope of the embodiments in the present disclosure. Those changes or adjustments of relative relationship without substantial changes of the technical content should also be considered within the category of implementation.

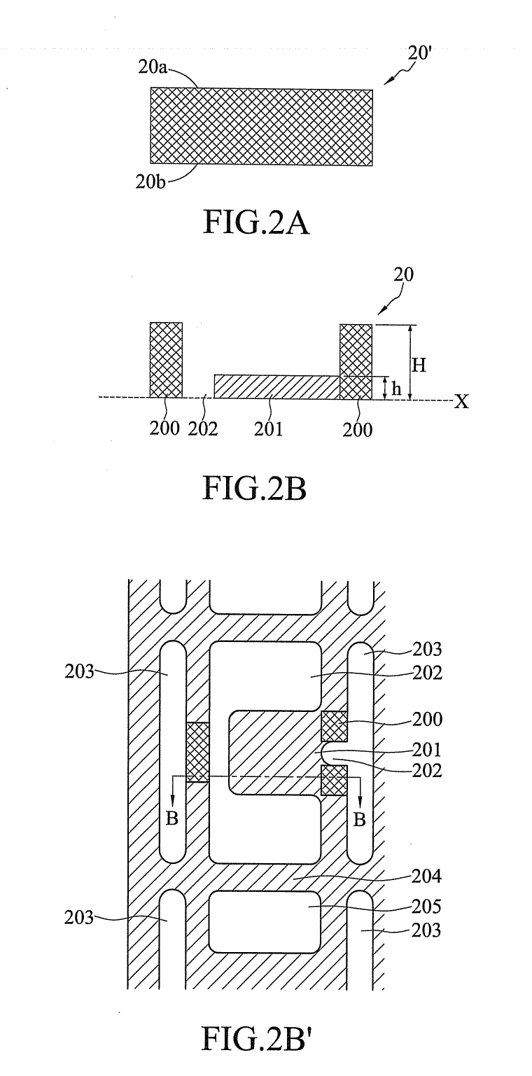

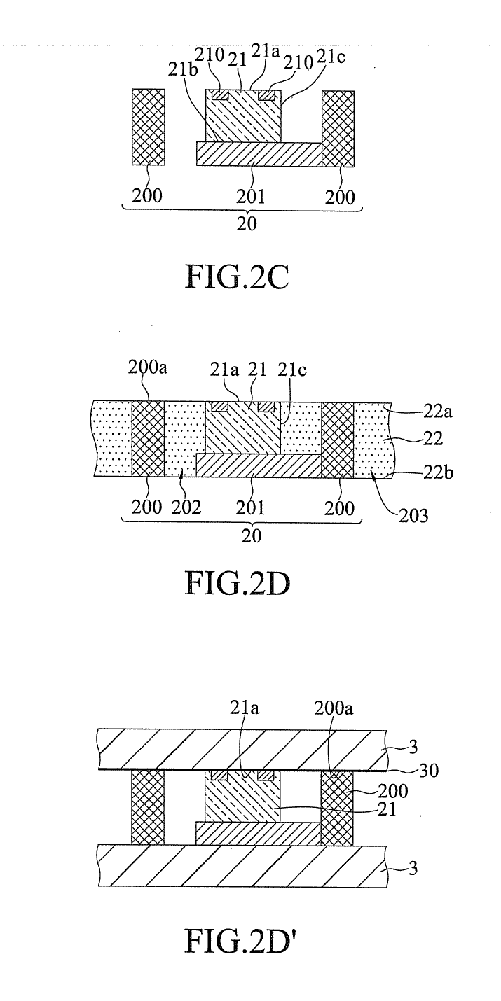

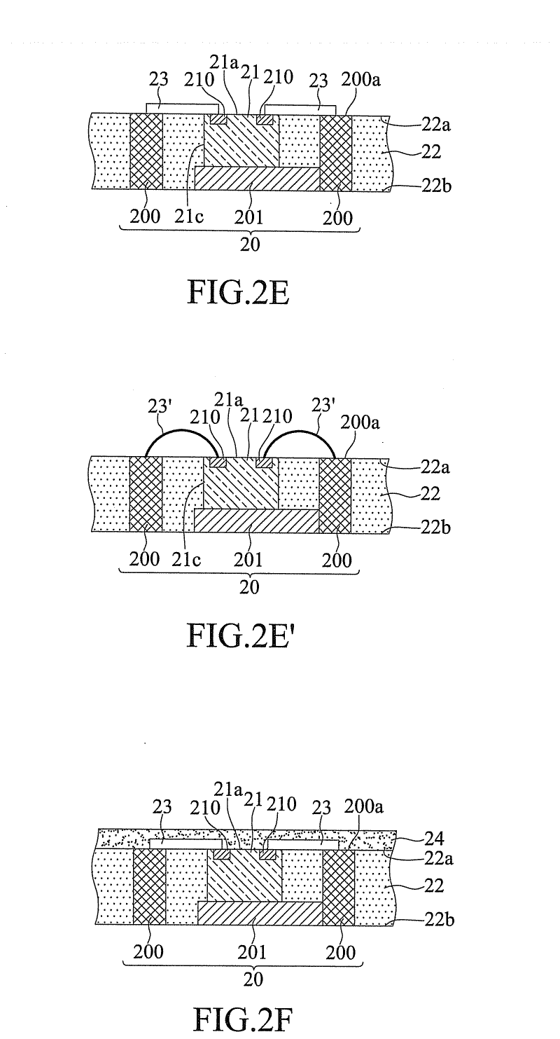

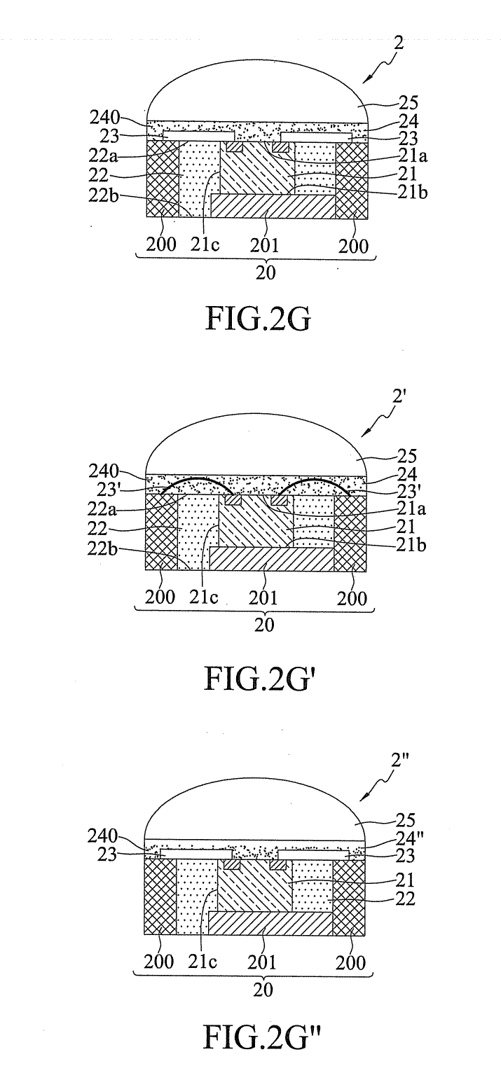

Please refer to FIGS. 2A-2G″, illustrating sectional scheme views of a method for manufacturing a package structure according to the present disclosure.

As shown in FIG. 2A, a metal substrate 20′ is provided, and the substrate 20′ has a first side 20a and a second side 20b opposing to the first side 20a.

As shown in FIGS. 2B and 2B′, etching and half-etching techniques are used to remove a portion of the material of the first side 20a of the substrate 20′ to form a plurality of placement portions 201. The first side 20a of the substrate 20′ and other portions of the first side 20a of the substrate 20′ which are not removed is utilized as a plurality of conductive portions 200, where a plurality of openings 202 and trenches 203 penetrating from the first side 20a of the substrate 20′ to the second side 20b of the substrate 20′, so as to form a plurality of carriers 20 such as lead frames.

In this embodiment, FIG. 2B is a sectional view of FIG. 2B′ along the line B-B. Since the manufacturing process for a periphery of each of the carriers 20 are identical, only one single carrier 20 is illustrated for convenience.

Moreover, each carrier 20 has at least one placement portion 201 and a plurality of conductive portions 200, and the placement portion 201 and the plurality of conductive portions 200 are in a same level reference such as a horizontal line “X” shown in FIG. 2B. The conductive portions 200 have a height “H” substantially larger than a height “h” of the placement portion 201. For example, the height “H” of the conductive portions 200 may be 300 μm, the height “h” of the placement portion 201 may be 130 μm, and the height “H” of the conductive portions 200 is no larger than 300 μm.

Also, the opening 202 is at a periphery of the placement portion 201, and the trench 203 serves as a cutting way.

In addition, a portion of the first side 20a of the substrate 20′ is removed to from a connection portion 204, and a penetrating portion is formed in the substrate 20′ to serve as a positioning hole 205 which facilitates a subsequent placement for a light emitting element.

As shown in FIG. 2C, a light emitting element 21 is disposed on the placement portion 201 of the carrier 20.

In this embodiment, the light emitting element 21 is a light emitting diode, having a non-emitting side 21b coupled to the placement portion 201, an emitting side 21a opposite to the non-emitting side 21b, and a lateral surface 21c adjacent the non-emitting side 21b and the emitting side 21a. The emitting side 21a has a plurality of electrodes 210 thereon, and the non-emitting side 21b can serve as a heat dissipating side of the light emitting element 21.

In an embodiment, the emitting side 21a of the light emitting element 21 is leveled with upper surfaces of the conductive portions 200 of the carrier 20.

Further, the conductive portions 200 are at exteriors of left and right lateral surfaces 21c of the light emitting element 21 as shown in FIG. 2B′. However, the positions of the conductive portions 200 can be designed upon actual needs, and are not limited thereto.

As shown in FIG. 2D, an encapsulant 22 is formed on the carrier 20, such that the encapsulant 22 encapsulates the light emitting element 21 and the placement portion 201 and directly covers the lateral surface 21c of the light emitting element 21. Also, the encapsulant 22 is formed between the lateral surface 21c of the light emitting element 21 and the conductive portions 200. The encapsulant 22 has a first surface 22a and a second surface 22b opposing to the first surface 22a, and the emitting side 21a of the light emitting element 21 and the upper surfaces 200a of the conductive portions 200 are exposed from the first surface 22a of the encapsulant 22.

In this embodiment, the encapsulant 22 is silicone, such as white glue, and thus the light only exits from the emitting side 21a of the light emitting element 21. Alternately, the encapsulant 22 can be, for example, transparent silicone, such that the light exits from the emitting side 21a and the lateral surface 21c of the light emitting element 21. The encapsulant 22 is further formed in the opening 202, as well as in the trench 203.

In an embodiment, the upper surface 200a of the conductive portion 200 and the emitting side 21a of the light emitting element 21 are leveled with the first surface 22a of the encapsulant 22.

Also, as shown in FIG. 2D′, a release film 30 is attached on an interior surface of a mold 3, such that the release film 30 is attached on the emitting side 21a and the upper surfaces 200a of the conductive portions 200. Accordingly, after the encapsulant 22 is formed and both the mold 3 and the release film 30 are removed, it can be ensured that both the emitting side 21a of the light emitting element 21 and the upper surfaces 200a of the conductive portions 200 are exposed from the first surface 22a of the encapsulant 22.

As shown in FIG. 2E, a conductive element 23, such as a conductive adhesive or a platted metal wiring, is formed on the first surface 22a of the encapsulant 22, such that the conductive element 23 electrically connects the electrodes 210 of the light emitting element 21 to the upper surfaces 200a of the conductive portions 200.

In this embodiment, the conductive element 23 is a conductive adhesive such as silver glue or copper paste, which is formed by coating. Since the encapsulant 22 covers the lateral surface 21c of the light emitting element 21 which adjacent the non-emitting side 21b and the emitting side 21a, when the conductive adhesive is utilized as the conductive element 23, the conductive adhesive will not overflow to the lateral surface 21c of the light emitting element 21. As such, the electrode 210 of the light emitting element 21 does not electrically conduct with an electrode (not shown) of the lateral surface 21c, so as to prevent from a short circuit.

In addition, a wire bonding process can be selected, where the conductive element 23′ is a conductive wire, as shown in FIG. 2E′.

As shown in FIG. 2F, a phosphor layer 24 having a plurality of phosphor powders 240 is formed on the first surface 22a of the encapsulant 22, so as to cover the emitting side 21a of the light emitting element 21, the upper surfaces 200a of the conductive portions 200, and the conductive element 23.

In this embodiment, the conductive adhesive serves as the conductive elements 23 for connecting the light emitting element 21 and the conductive portions 200. Accordingly, there is no need to consider the curvature of the conventional wire, and thus the phosphor layer 24 can be thinned according to actual needs in order to reduce the height of the overall structure.

As shown in FIG. 2G, a protection layer (not shown) for protecting the phosphor layer 24 or a light transmitting layer 25 of lens is formed on the phosphor layer 24, and a cutting process is performed along the trench 203 as shown in FIG. 2B′. Accordingly, a plurality of light emitting package structures 2 are produced, and the conductive portions 200 and the connection portion 204 are inlaid at the lateral surfaces of the encapsulant 22, such that the conductive portions 200 and the connection portion 204 are exposed from the lateral surfaces of the encapsulant 22.

Moreover, if the process shown in FIG. 2G is followed by the process shown in FIG. 2E′, a package structure T shown in FIG. 2G′ would be obtained.

In addition, as shown in the package structure 2″ of FIG. 2G″, the phosphor powders 240 may be concentrated at one side of the phosphor layer 24″.

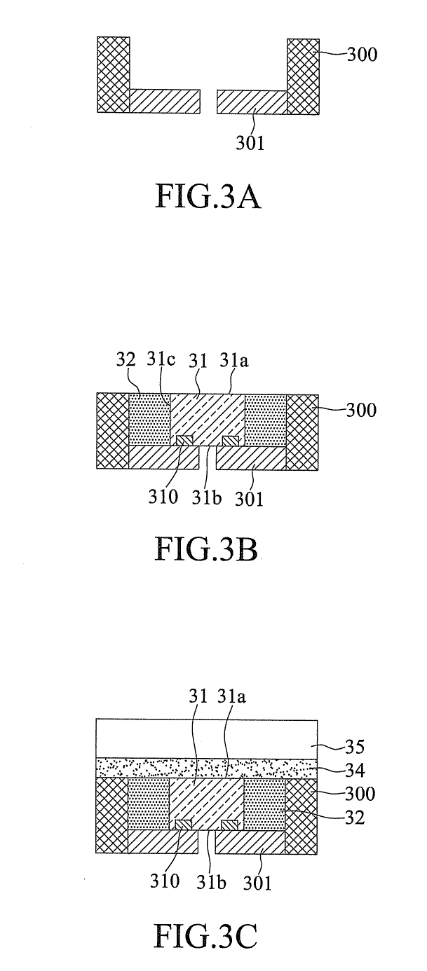

FIGS. 3A-3C illustrate sectional scheme views of another embodiment of a method for manufacturing a package structure according to the present disclosure.

As shown in FIG. 3A, a carrier is formed from a metal substrate by etching and semi-etching processes. The carrier has a plurality of conductive portions 300 and a placement portion 301 formed on one end of the conductive portions and inwardly extended. As illustrated in FIG. 3A, the placement portions 301 extending to each other are formed on respective ends of two conductive portions 300, and the placement portions 301 extending to each other do not contact each other.

As shown in FIG. 3B, a light emitting element 31 is disposed on the placement portion 301. The light emitting element 31 is a light emitting diode having a non-emitting side 31b coupled to the placement portion 301, an emitting side 31a opposing to the non-emitting side 31b, a lateral surface 31c adjacent the non-emitting side 31b and the emitting side 31a. The non-emitting side 31b has a plurality of electrodes 310 thereon, such that the light emitting element 31 is disposed and electrically connected to the placement portion 301 in a flip-chip manner.

An encapsulant 32, such as silicone or white glue, covering the lateral surface 31c of the light emitting element 31 is then formed, and the emitting side 31a of the light emitting element 31 and the conductive portions 300 are exposed from the encapsulant 32.

As shown in FIG. 3C, a phosphor layer 34 may then be formed on the emitting side 31a of the light emitting element 31. In an embodiment, a protection layer or a light transmitting layer 35 may be further formed on the phosphor layer.

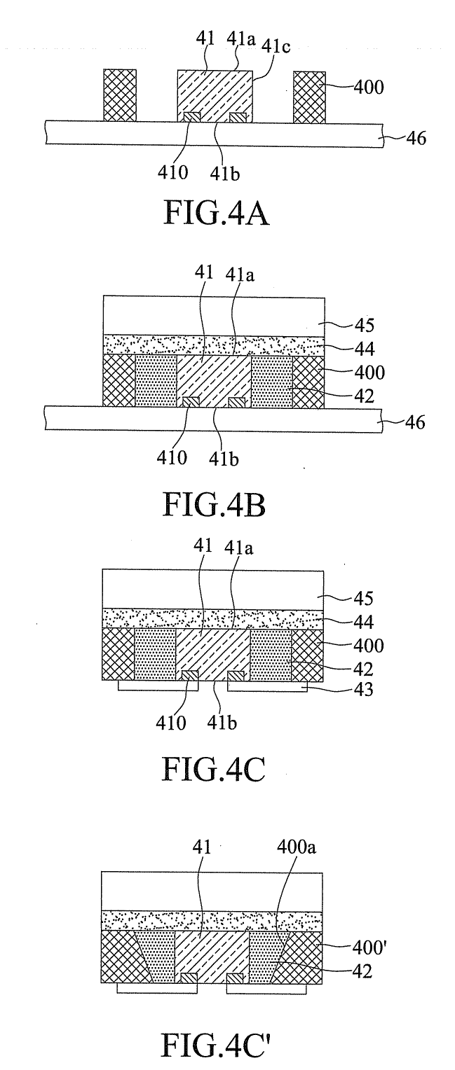

FIGS. 4A-4C′ illustrate sectional scheme views of another embodiment of a method for manufacturing a package structure according to the present disclosure.

As shown in FIG. 4A, a carrier having a plurality of conductive portions 400 and a light emitting element 41 are disposed on a carrying member 46. The carrying member 46, for example, is a release film.

The light emitting element 41 is a light emitting diode having a non-emitting side 41b coupled to the carrying member 46, an emitting side 41a opposing to the non-emitting side 41b, and a lateral surface 41c adjacent the non-emitting side 41b and the emitting side 41a. The non-emitting side 41b has a plurality of electrodes 410 thereon.

As shown in FIG. 4B, an encapsulant 42, such as silicone or white glue, covering the lateral surface 41c of the light emitting element 41 is then formed, and the emitting side 41a of the light emitting element 41 and the conductive portions 400 are exposed from the encapsulant 42.

A phosphor layer 44 may then be formed on the emitting side 41a of the light emitting element 41. In one embodiment, a protection layer or a light transmitting layer 45 may be further formed on the phosphor layer 44.

As shown in FIG. 4C, the carrying member 46 is removed, and the light emitting element 41 and the conductive portions 400 are electrically connected by conductive members 43.

FIG. 4C′ illustrates a sectional scheme view of another embodiment of a package structure according to the present disclosure. The package structure of this embodiment is substantially equivalent to previous package structures, except that a curved surface or beveled surface 400a is formed at one side of a conductive portion 400 corresponding to the light emitting element 41, and a transparent encapsulant 42 is formed between the conductive portion 400′ and the light emitting element 41 for reflecting light from a light source at a lateral surface of the light emitting element 41.

FIGS. 5A-5B illustrate sectional and top scheme views of a package structure according to the present disclosure. The package structure of this embodiment is substantially equivalent to previous package structures, except that a carrier is formed from a metal substrate through an etching process. The carrier has a plurality of openings 500a for accommodating a light emitting element 51, and conductive portions 500 are disposed at both sides of the openings 500a to provide electrical connection between the light emitting element 51 and the conductive portions 500. Further, trenches 500b are formed between the openings 500a, such that when an encapsulant 52 is subsequently formed between the light emitting element 51 and the conductive portions 500, the encapsulant 52 can be injected through the trenches 500b to encapsulate a periphery of the light emitting element 51.

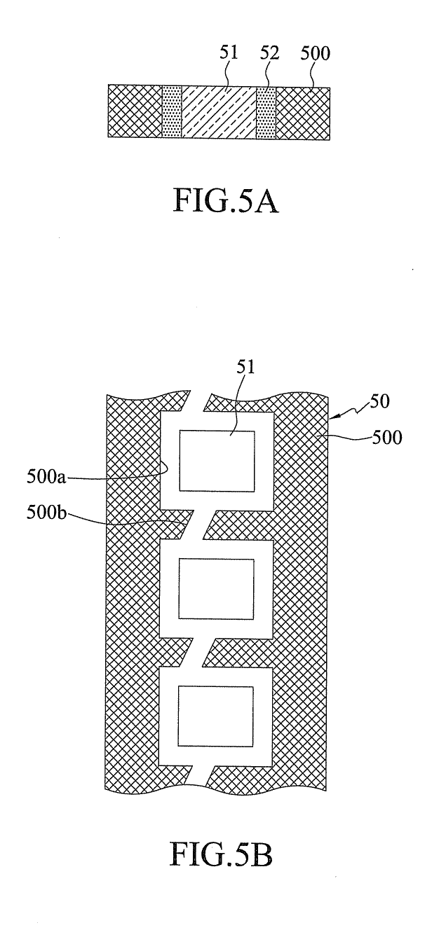

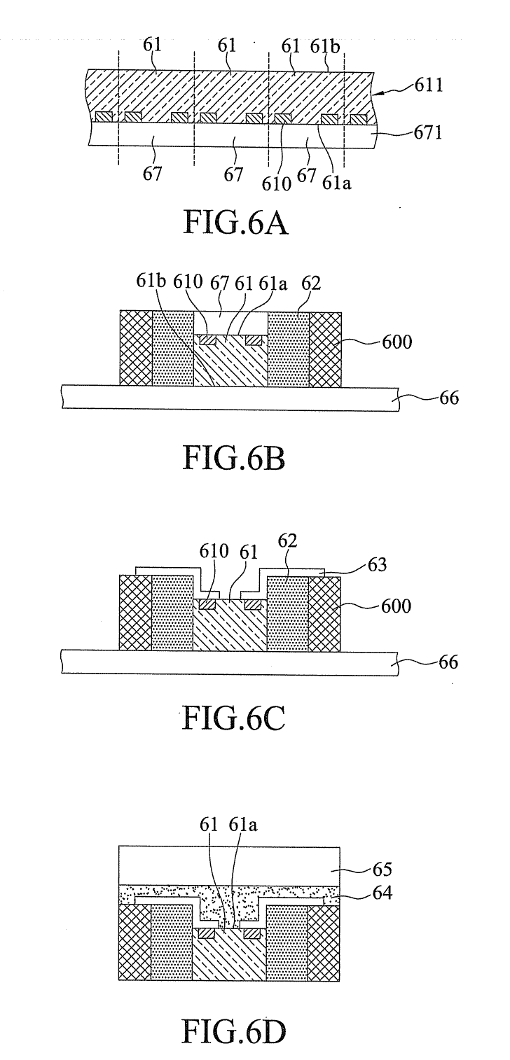

FIGS. 6A-6D illustrate sectional scheme views of another embodiment of a method for manufacturing a package structure according to the present disclosure. The package structure of this embodiment is substantially equivalent to previous package structures, except that the light emitting element is covered by a release film 671 thereon.

As shown in FIG. 6A, a substrate 611 including a plurality of light emitting elements 61 is disposed on entirety of a release film 671.

Afterward, the substrate 611 and the entirety of the release film 671 are cut with respect to each of the light emitting elements 61, so as to form a plurality of light emitting elements 61 with a release film 67 attached on surfaces thereof. In one embodiment, the light emitting element 61 has opposing non-emitting side 61b and emitting side 61a, the emitting side 61a has a plurality of electrodes 610, and the release film 67 is attached on the emitting side 61a.

As shown in FIG. 6B, the light emitting element 61 with a release film 67 attached on the surface thereof and the carrier having a plurality of conductive portions 600 are disposed on a carrying member 66, wherein the light emitting element 61 is disposed on the carrying member 66 through the non-emitting side 61b thereof. Then, an encapsulant 62 is formed between the light emitting element 61 and the conductive portions 600. Since the release film 67 is attached on the emitting side 61a of the light emitting element 61, the emitting side 61a is free of contamination during the formation of the encapsulant 62.

As shown in FIG. 6C, the release film 67 on the emitting side 61a of the light emitting element 61 is removed, and an electrode 610 of the light emitting element 61 and the conductive portions 600 are electrically connected. In this embodiment, the electrical connection between the light emitting element 61 and the conductive portions 600 is achieved by coating a conductive material 63, which can also be performed in other manners such as wire bonding. Also, in an embodiment, a height of the conductive portions 600 is approximately the same as that of the encapsulant 62, and a height of the light emitting element 61 is lower than that of the encapsulant 62, such that a segment of difference in height is formed between the light emitting element 61 and the encapsulant 62.

As shown in FIG. 6D, a phosphor layer 64 may then be formed on the emitting side 61a of the light emitting element 61. In an embodiment, a protection layer or a light transmitting layer 65 may be further formed on the phosphor layer 64. Then, the carrying member 66 is removed.

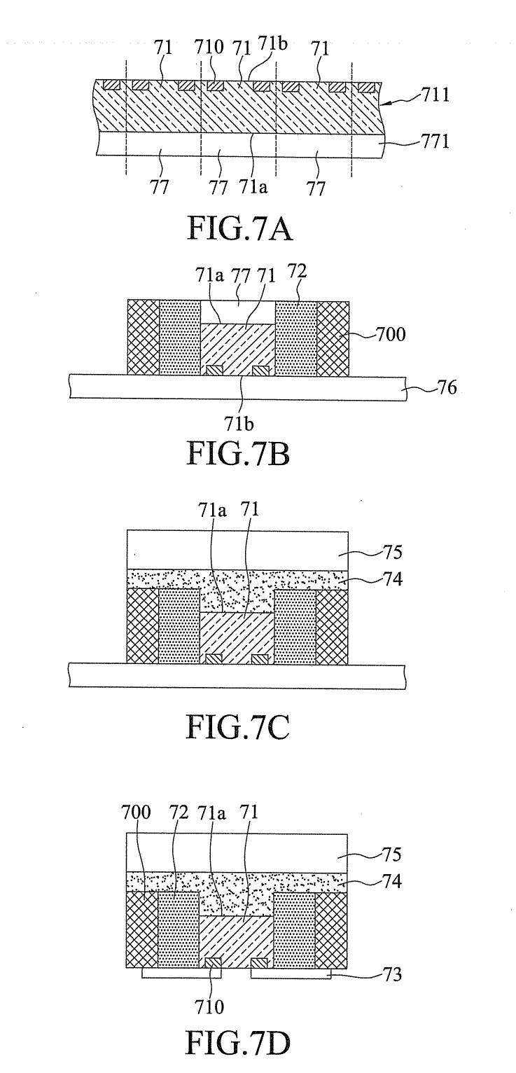

FIGS. 7A-7D illustrate sectional scheme views of another embodiment of a method for manufacturing a package structure according to the present disclosure. The package structure of this embodiment is substantially equivalent to previous package structures, except that the light emitting element 71 is covered by a release film 771 thereon and is electrically connected to a carrier in a flip-chip manner.

As shown in FIG. 7A, a substrate 711 including a plurality of light emitting elements 71 is disposed on entirety of a release film 771.

Afterward, the substrate 711 and the entirety of the release film 771 are cut with respect to each of the light emitting elements 71, so as to form a plurality of light emitting elements 71 with a release film 77 attached on surfaces thereof. In one embodiment, the light emitting element 71 has opposing non-emitting side 71b and emitting side 71a, the non-emitting side 71b has a plurality of electrodes 710, and the release film 77 is attached on the emitting side 71a.

As shown in FIG. 7B, the light emitting element 71 with a release film 77 attached on the surface thereof and the carrier having a plurality of conductive portions 700 are disposed on a carrying member 76. The light emitting element 71 is disposed on the carrying member 76 through the non-emitting side 71b thereof. Then, an encapsulant 72 is formed between the light emitting element 71 and the conductive portions 700. Since the release film 77 is attached on the emitting side 71a of the light emitting element 71, the emitting side 71a is free of contamination during the formation of the encapsulant 72.

As shown in FIG. 7C, the release film 77 on the emitting side 71a of the light emitting element 71 is removed, and a phosphor layer 74 may be then formed on the emitting side 71a of the light emitting element 71. In an embodiment, a protection layer or a light transmitting layer 75 may be further formed on the phosphor layer 74.

As shown in FIG. 7D, the electrode 710 of the light emitting element 71 and the conductive portions 700 are electrically connected through conductive members 73.

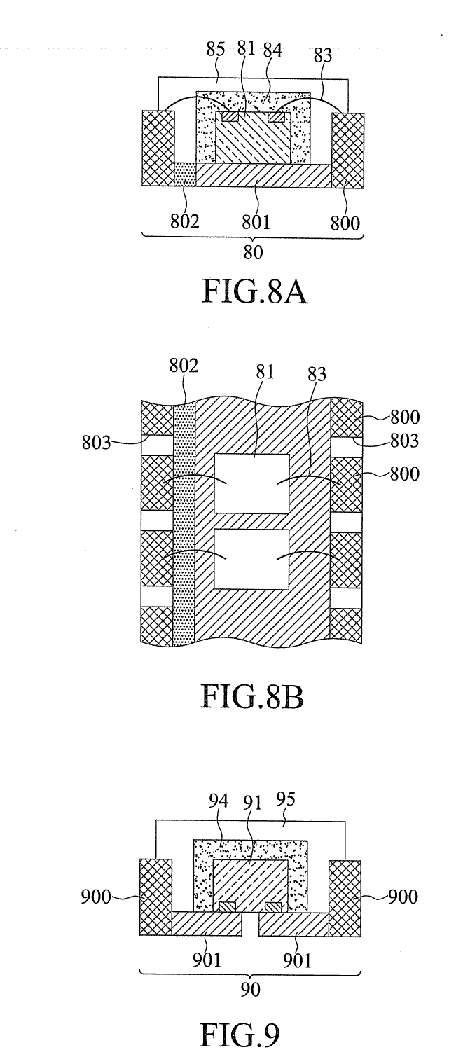

FIGS. 8A-8B illustrate sectional and top scheme views of another embodiment of a package structure according to the present disclosure. The package structure of this embodiment is substantially equivalent to previous package structures, except that a carrier 80 is formed from a metal substrate through etching and semi-etching processes. The carrier 80 has a placement portion 801 and a plurality of conductive portions 800 disposed at both sides of the placement portion 801, wherein the placement portion 801 is electrically conducted to one side of the conductive portions and an insulating adhesive 802 is filled between the placement portion 801 and another side of the conductive portions to prevent both sides of the conductive portions from short. In addition, a trench 803 is formed between the conductive portions 800 longitudinally aligned conductive when the metal substrate is etched. A light emitting element 81 is disposed on the placement portion 801, and the light

A light emitting element 81 is electrically connected to both sides of the conductive portions 800 through wires 83. Also, a phosphor layer 84 is formed on a surface of the light emitting element 81, and a light transmitting layer 85 encapsulating the phosphor layer 84 and the wires 83 is formed on the phosphor layer 84. The light transmitting layer 85 is, for example, transparent silicone, and is effectively secured on the carrier 80 with the previously formed trench 803.

FIG. 9 illustrates a sectional scheme view of another embodiment of a package structure according to the present disclosure. The package structure of this embodiment is substantially equivalent to previous package structures, except that a carrier 90 is provided. The carrier 90 has a plurality of conductive portions 900 and a placement portion 901 formed on one end of the conductive portions 900 and inwardly extended. As illustrated in FIG. 9, the placement portions 901 extending to each other are formed on respective ends of the two conductive portions 900, and the placement portions 901 extending to each other do not contact each other, such that a light emitting element 91 is disposed and electrically connected to the placement portion 901 in a flip-chip manner. A phosphor layer 94 is formed on the surfaces of the light emitting element 91, and a light transmitting layer 95 encapsulating the phosphor layer 94 is further formed.

Further, a Zener diode is disposed in the aforementioned package structures to stabilize the voltage. In addition, for the light emitting element that the light exits from the lateral surface, a side of the conductive portions in aforementioned package structures corresponding to the light emitting element can selectively be formed as a curved surface or beveled surface (not shown), so as to form a three-dimensional LED package structure. Also, the light emitting elements in aforesaid package structures can be selected to be electrically connected to the conductive portions of the carrier in a vertical or flip-chip manner.

The above embodiments only exemplarily specify the concept and effect of the present disclosure, but not intend to limit the invention. Any person skilled in the art can perform modifications and adjustments on the above embodiments without departing the spirit and category of the present disclosure. Thus, the present disclosure should fall within the scope of the appended claims.

What is claimed is:

1. A package structure, comprising:
a light emitting element having an emitting side, a non-emitting side opposing to the emitting side, and a lateral surface adjacent the emitting side and the non-emitting side;
a first conductive portion having an upper surface and a lower surface opposing to the upper surface;
an encapsulant filling in a space between the lateral surface of the light emitting element and the first conductive portion with the lateral surface of the light emitting element covered by the encapsulant and the emitting side of the light emitting element exposed from the encapsulant.

2. The package structure of claim 1, further comprising a placement portion, wherein the first conductive portion and the placement portion form a carrier, and the light emitting element is disposed on the placement portion through the non-emitting side.

3. The package structure of claim 2, further comprising a second conductive portion, wherein the placement portion is electrically connected to the first conductive portion and is spaced apart from the second conductive portion by an insulating adhesive.

4. The package structure of claim 2, wherein the encapsulant is formed on the placement portion, and the first conductive portion has a height higher than a height of the placement portion.

5. The package structure of claim 4, wherein the height of the first conductive portion is smaller than or substantially equal to 300 μm.

6. The package structure of claim 2, wherein the carrier has a through opening filled with the encapsulant.

7. The package structure of claim 6, wherein the through opening is formed at a periphery of the placement portion.

8. The package structure of claim 1, wherein the emitting side of the light emitting element is substantially leveled with the upper surface of the first conductive portion.

9. The package structure of claim 1, wherein the light emitting side of the light emitting element is substantially leveled with or lower than a surface of the encapsulant.

10. The package structure of claim 1, further comprising a conductive element electrically connecting the light emitting element to the first conductive portion.

11. The package structure of claim 10, wherein the conductive element is a conductive adhesive, a wire or a metal circuit.

12. The package structure of claim 1, further comprising a phosphor layer formed on the emitting side of the light emitting element.

13. The package structure of claim 12, further comprising an additional layer formed on the phosphor layer, wherein the additional layer is a protection layer or a light transmitting layer.

14. The package structure of claim 1, wherein a side of the first conductive portion corresponding to the light emitting element is a curved surface or a beveled surface.

15. The package structure of claim 1, wherein the light emitting element has an electrode electrically connected to the upper surface or the lower surface of the first conductive portion.

16. A method of manufacturing a package structure, comprising:
providing a light emitting element having an emitting side, a non-emitting side opposing to the emitting side, and a lateral surface adjacent the emitting side and the non-emitting side;
forming a first conductive portion having an upper surface and a lower surface opposing to the upper surface;
encapsulating the light emitting element and the first conductive portion and filling a space between the lateral surface of the light emitting element and the first conductive portion by an encapsulant with the lateral surface of the light emitting element covered by the encapsulant and the emitting side of the light emitting element exposed from the encapsulant.

17. The method of claim 16, further comprising forming a placement portion, wherein the placement portion and the first conductive portion form a carrier.

18. The method of claim 17, wherein providing the light emitting element comprises disposing the light emitting element on the placement portion through the non-emitting side.

19. The method of claim 17, wherein encapsulating the light emitting element and the first conductive portion by the encapsulant comprises disposing the encapsulant on the placement portion, wherein the first conductive portion has a height higher than a height of the placement portion.

20. The method of claim 19, wherein the height of the first conductive portion is smaller than or substantially equal to 300 μm.

21. The method of claim 17, wherein the carrier is formed by:
providing a substrate having a first side and a second side opposing to the first side; and
removing a portion of the first side of the substrate to form the placement portion with a remaining portion of the first side of the substrate serving as the first conductive portion.

22. The method of claim 21, wherein the carrier having a through opening penetrating from the first side of the substrate to the second side of the substrate.

23. The method of claim 22, further comprising filling the through opening with the encapsulant.

24. The method of claim 22, wherein the through opening is formed at a periphery of the placement portion.

25. The method of claim 17, further comprising forming a second conductive portion, wherein the placement portion is electrically connected to the first conductive portion, and is spaced apart from the second conductive portion by an insulating adhesive .

26. The method of claim 16, wherein the emitting side of the light emitting element is substantially leveled with the upper surface of the first conductive portion.

27. The method of claim 16, wherein the light emitting side of the light emitting element is substantially leveled with or lower than a surface of the encapsulant.

28. The method of claim 16, further comprising disposing a conductive element electrically connecting the light emitting element to the first conductive portion.

29. The method of claim 28, wherein the conductive element is a conductive adhesive, a wire or a metal circuit.

30. The method of claim 16, further comprising forming a phosphor layer on the emitting side of the light emitting element.

31. The method of claim 30, further comprising forming an additional layer on the phosphor layer, wherein the additional layer is a protection layer or a light transmitting layer.

32. The method of claim 16, wherein a side of the first conductive portion corresponding to the light emitting element is a curved surface or a beveled surface.

33. The method of claim 16, wherein the light emitting element has an electrode electrically connected to the upper surface or the lower surface of the first conductive portion.

34. The method of claim 21, wherein the substrate is formed with a plurality of openings, and the light emitting element is disposed in one of the plurality of openings.

35. The method of claim 34, further comprising forming a trench connecting adjacent two of the plurality of openings.

36. The method of claim 16, further comprising disposing a release film on the emitting side of the light emitting element, and removing the release film after encapsulating.

37. A carrier, comprising:
a first opening configured to dispose a first light emitting element therein; and
a first conductive portion and a second conductive portion disposed at two sides of the first opening, respectively, wherein the first conductive portion has a height smaller than or substantially equal to 300 μm.

38. The carrier of claim 37, further comprising a placement portion with the first light emitting element disposed thereon, wherein the height of the first conductive portion is higher than a height of the placement portion.

39. The carrier of claim 38, wherein the placement portion is electrically connected to the first conductive portion, and is spaced apart from the second conductive portion by an insulating adhesive.

40. The carrier of claim 38, further comprising a through opening formed at a periphery of the placement portion.

41. The carrier of claim 37, wherein a side of the first conductive portion is a curved surface or a beveled surface.

42. The carrier of claim 37, further comprising a second opening connecting to the first opening by a trench and configured to dispose a second light emitting element therein.

43. The carrier of claim 37, wherein the first conductive portion is spaced apart from the second conductive portion by a trench.
